(19) United States
(12) Patent Application Publication
(10) Pub. No.: US 2023/0027688 A1
(43) Pub. Date: Jan. 26, 2023

(54) LARGE OBJECT PACKING FOR STORAGE EFFICIENCY

(71) Applicant: EMC IP Holding Company LLC, Hopkinton, MA (US)

(72) Inventors: Philip N. Shilane, Newtown, MA (US); George Mathew, Belmont, CA (US); Abhinav Duggal, Santa Clara, CA (US)

(21) Appl. No.: 17/383,255

(22) Filed: Jul. 22, 2021

(51) Int. Cl. G06F 16/2455; G06F 16/27; G06F 16/28; G06F 16/23

(52) U.S. Cl. CPC G06F 16/24556; G06F 16/278; G06F 16/288; G06F 16/2358; G06F 16/24552

(57) ABSTRACT

One example method includes receiving data, partitioning the data according to their respective similarity groups, and the similarity groups collectively define a range of similarity groups, deduplicating the data after the partitioning, packing unique data segments remaining after deduplicating into one or more compression regions, compressing the compression regions, and writing an object, that includes the compression regions, to a durable log. The deduplicating and compressing for a similarity group may be performed by a dedup-compression instances uniquely assigned to that similarity group.

### FIELD OF THE INVENTION

Embodiments of the present invention generally relate to data storage. More particularly, at least some embodiments of the invention relate to systems, hardware, software, computer-readable media, and methods for packing data into larger units based on the similarity of the data.

### BACKGROUND

Some data storage efficiencies may be realized by packing data into larger units. One conventional system creates 4.5 MB containers of compression regions so that writes to a RAID system are efficient. As another example, some SSD devices may group 4 KB page writes into a larger block that is written to media as part of an overall design to maintain the lifespan of the media. While beneficial in some respects, approaches such as these have room for improvement in areas such as routing mechanisms, latency, and garbage collection.

### BRIEF DESCRIPTION OF THE DRAWINGS

In order to describe the manner in which at least some of the advantages and features of the invention may be obtained, a more particular description of embodiments of the invention will be rendered by reference to specific embodiments thereof which are illustrated in the appended drawings. Understanding that these drawings depict only typical embodiments of the invention and are not therefore to be considered to be limiting of its scope, embodiments of the invention will be described and explained with additional specificity and detail through the use of the accompanying drawings.

FIG. 1 discloses aspects of an example architecture for some embodiments of the invention.

FIG. 2 discloses aspects of an example packing module.

FIG. 3 discloses an example container format according to some example embodiments.

FIG. 4 discloses an example method for large object packing.

FIG. 5 discloses an example computing entity operable to perform any of the claimed methods, processes, and operations.

### DETAILED DESCRIPTION OF SOME EXAMPLE EMBODIMENTS

Embodiments of the present invention generally relate to data storage. More particularly, at least some embodiments of the invention relate to systems, hardware, software, computer-readable media, and methods for packing data into larger units based on the similarity of the data.

In general, example embodiments of the invention may receive data written by clients, and then deduplicate the data. After deduplication of the data, which may be performed on a segment basis, any unique segments that remain may be packed into one or more compression regions. The compression regions may be written to a durable post-deduplication log, and packed into a larger object, that is, an object larger than any of the compression regions. The larger object may then be logged for persistence, and written to an underlying object store. After the larger object is written to the underlying object store, the compression regions in the log may be released. In some embodiments, the larger object need not be logged for persistence. The incoming data from the client writes may be partitioned based on similarity groups so that, as a consequence of the partitioning, the larger object may contain only data that has been labeled as being similar.

Embodiments of the invention, such as the examples disclosed herein, may be beneficial in a variety of respects. For example, and as will be apparent from the present disclosure, one or more embodiments of the invention may provide one or more advantageous and unexpected effects, in any combination, some examples of which are set forth below. It should be noted that such effects are neither intended, nor should be construed, to limit the scope of the claimed invention in any way. It should further be noted that nothing herein should be construed as constituting an essential or indispensable element of any invention or embodiment. Rather, various aspects of the disclosed embodiments may be combined in a variety of ways so as to define yet further embodiments. Such further embodiments are considered as being within the scope of this disclosure. As well, none of the embodiments embraced within the scope of this disclosure should be construed as resolving, or being limited to the resolution of, any particular problem(s). Nor should any such embodiments be construed to implement, or be limited to implementation of, any particular technical effect(s) or solution(s). Finally, it is not required that any embodiment implement any of the advantageous and unexpected effects disclosed herein.

In particular, one advantageous aspect of at least some embodiments of the invention is that by maintaining data separation, that is, creating large objects that only include similar data, embodiments may support parallelized forms of garbage collection. As another example, an embodiment may help to maintain a consistent routing that may support in-memory caches of data, and may correspondingly reduce the latency of cross-service communications. As will be apparent from this disclosure, embodiments of the invention may provide various other useful features and functionalities.

### A. General Aspects of an Example Operating Environment

The following is a discussion of aspects of example operating environments for various embodiments of the invention. This discussion is not intended to limit the scope of the invention, or the applicability of the embodiments, in any way.

In general, embodiments of the invention may be implemented in connection with systems, software, and components, that individually and/or collectively implement, and/or cause the implementation of, data protection operations which may include, but are not limited to, data replication operations, IO replication operations, data read/write/delete operations, data deduplication operations, data backup operations, data restore operations, data cloning operations, data archiving operations, and disaster recovery operations. More generally, the scope of the invention embraces any operating environment in which the disclosed concepts may be useful.

New and/or modified data collected and/or generated in connection with some embodiments, may be stored in a data protection environment that may take the form of a public or private cloud storage environment, an on-premises storage environment, and hybrid storage environments that include public and private elements. Any of these example storage environments, may be partly, or completely, virtualized. The storage environment may comprise, or consist of, a datacenter which is operable to service read, write, delete, backup, restore, and/or cloning, operations initiated by one or more clients or other elements of the operating environment. Where a backup comprises groups of data with different respective characteristics, that data may be allocated, and stored, to different respective targets in the storage environment, where the targets each correspond to a data group having one or more particular characteristics.

Example cloud computing environments, which may or may not be public, include storage environments that may provide data protection functionality for one or more clients. Another example of a cloud computing environment is one in which processing, data protection, and other, services may be performed on behalf of one or more clients. Some example cloud computing environments in connection with which embodiments of the invention may be employed include, but are not limited to, Microsoft Azure, Amazon AWS, Dell EMC Cloud Storage Services, and Google Cloud. More generally however, the scope of the invention is not limited to employment of any particular type or implementation of cloud computing environment.

In addition to the cloud environment, the operating environment may also include one or more clients that are capable of collecting, modifying, and creating, data. As such, a particular client may employ, or otherwise be associated with, one or more instances of each of one or more applications that perform such operations with respect to data. Such clients may comprise physical machines, or virtual machines (VM)

As used herein, the term ‘data’ is intended to be broad in scope. Thus, that term embraces, by way of example and not limitation, data segments such as may be produced by data stream segmentation processes, data chunks, data blocks, atomic data, emails, objects of any type, files of any type including media files, word processing files, spreadsheet files, and database files, as well as contacts, directories, sub-directories, volumes, and any group of one or more of the foregoing.

Example embodiments of the invention are applicable to any system capable of storing and handling various types of objects, in analog, digital, or other form. Although terms such as document, file, segment, block, or object may be used by way of example, the principles of the disclosure are not limited to any particular form of representing and storing data or other information. Rather, such principles are equally applicable to any object capable of representing information.

As used herein, the term ‘backup’ is intended to be broad in scope. As such, example backups in connection with which embodiments of the invention may be employed include, but are not limited to, full backups, partial backups, clones, snapshots, and incremental or differential backups.

### B. Overview

In general, example embodiments of the invention embrace, among other things, a packer module that forms large objects from compression regions before writing to an underlying object storage system to align with the stripe size of erasure coding to avoid mirroring. In one example use case, an instance of the DellEMC ECS object storage may be optimized for 128 MB object sizes to avoid mirroring overheads. Some possible advantages of packing smaller data structures into a large object based on a consistent property, such as data similarity for example, may include better write throughput, and reduced garbage collection overheads of the underlying object storage system. Embodiments of the invention may partition incoming data based on similarity groups, log data for persistence, and maintain the separation between dissimilar data when forming large objects, which in turn may support a parallelized form of garbage collection (GC).

### C. Aspects of an Example Operating Environment

### C.1 Similarity Groups

By way of background, at least some embodiments of the invention may operate in connection with one or more similarity groups. As used herein, a similarity group is an example of a data structure and embraces a group of data segments that are similar to each other, but unique. Some similarity groups may additionally include some identical segments. Similarity groups may be used by a deduplication process to track which sequences of segments are similar. A similarity group may reference multiple different compression regions, and similarity groups may be updated as a new, related, compression region is referenced by a similarity group

More particularly, similarity groups may record a mapping from compression regions to lists of fingerprints. During deduplication, when an object is partitioned into slices, a similarity group ID may be generated for each slice, and the slice may be deduplicated against the similarity group with that ID. Various techniques may be employed for generating a similarity group ID for a slice, such as selecting a few bytes from each fingerprint and selecting the minimal, or maximal, value. Other techniques that may be employed calculate hashes over the fingerprints. After deduplicating a slice against a similarity group, any remaining unique segments from the slice may be concatenated together, compressed, and written as a compression region. The similarity group may be updated to record the compression region and its fingerprints both for future deduplication purposes and reading back the object later.

### C.2 Example Operating Environments

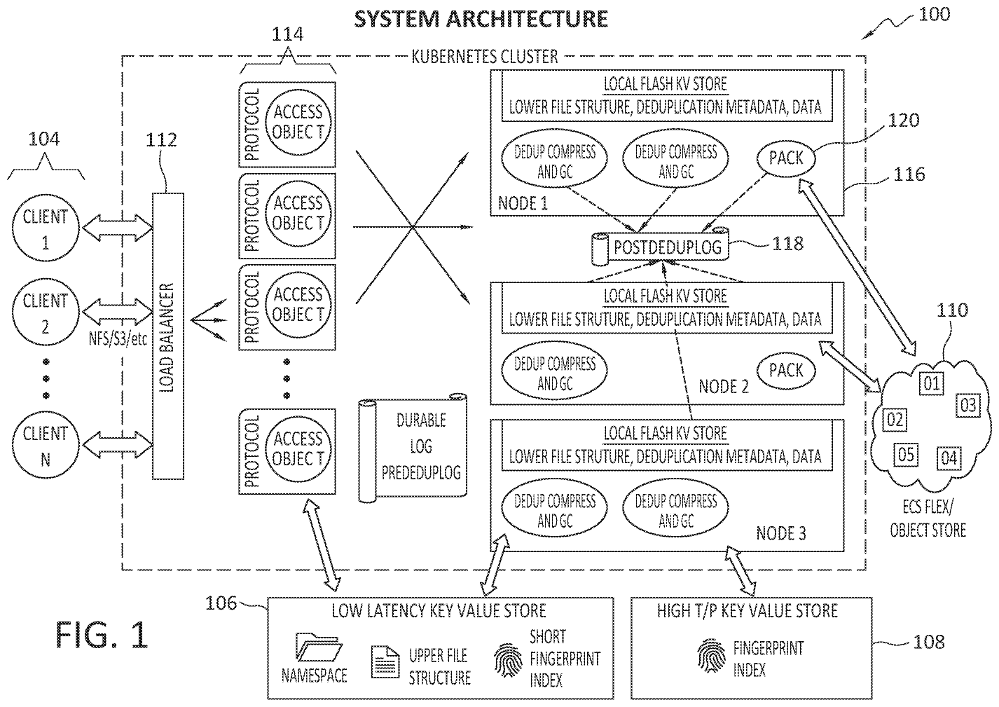

In view of the foregoing discussion, and with particular attention now to FIG. 1, one example of an operating environment for embodiments of the invention is denoted generally at 100. In general, the operating environment 100 may comprise a cluster 102, such as a Kubernetes cluster for example, that may received reads and writes from one or more clients 104, and may interact with a low latency key value store 106, and a high throughput key value store 108. As well, the example operating environment 100 may comprise an object store 110, one example of which may be the DellEMC ECS Flex/Object Store.

In further detail, the clients 104 may write data through a load balancer 112 that redirects to an instance of an access object service 114 that may handle the namespace and upper part of a file representation, such as the DellEMC DataDomain Lp tree for example. The access object service 114 may create folders, and beginning parts of files, such as parts of an Lp tree, which may also be referred to as access objects. As data is written by the clients 104, the data is added to the access object of the file. The access object service 114 may also split files into 8K, or other size, segments.

When forming an L1, an access object of the access object service 114 may calculate a similarity group ID for the L1 based on the content of the segments in the L1, hashes of the segments, or other consistent properties. The access object may then, based on the similarity group ID, direct the data of the L1, that is, the L0 segments of that L1, to a specific instance of a dedup-compress service 116, which is responsible for performing deduplication of the segments using the respective fingerprints that correspond to the segments. Note that the Lp tree refers to a configuration in which ‘p’ denotes the level L of the Lp tree. Thus, L6 embraces an entire file, while L0 denotes 8K segments from a user, and L1 refers to a group of consecutive L0 segments, which may be referenced by their respective fingerprints.

The deduplication process indicated in FIG. 1 may implement a deduplication algorithm, one example of which is the DataDomain deduplication algorithm. For an incoming L1's worth of data, the fingerprints of the segments may be compared against an in-memory cache to determine which fingerprints are duplicates and which are unique. The cache may be reloaded periodically based on accessing a fingerprint index that can be used to reference, for example, metadata comprising ^{˜}1000 consecutively written fingerprints stored to a key value store. In at least some embodiments, all of the segments in an L1 have the same similarity group ID, that is, those segments all belong to the same similarity group.

After deduplicating the segments, any segments that remain, that is, any unique segments, may be packed into one or more compression regions, compressed, written to a durable post-deduplication log 118, and packed into a larger object that may be written to the underlying object store 110. Once logged, the data is safe, that is, it has been stored in the durable post-deduplication log 118, although may not yet be stored in the object store 110, and can be read out in response to a read request. Because the post-deduplication log 118 may be in flash memory, reads directed to the post-deduplication log 118 may be performed quickly. Eventually, the data in the post-deduplication log 118 may be moved to the object store 110 which may not provide read performance as fast as flash memory, but is less expensive than flash memory.

As noted elsewhere herein, example embodiments may partition incoming data by similarity group ID and then assign a dedup-compress instance 116 to a respective range of similarity group IDs that the dedup-compress instances 116 are each uniquely responsible for. As an example, if similarity group IDs range from 0 to 1000 and there are 4 dedup-compress instances 116, the dedup-compress instances 116 may be assigned similarity group IDs 0-249, 250-499, 500-749, and 750-1000, respectively. A read after write may be directed to the appropriate dedup-compress instance 116 where data may be uniquely cached and accessed without using a distributed lock manager.

Thus, embodiments of the invention may maintain the partitioning of data into similarity groups even as segments are logged and packed into a larger object that will be written to object storage by a packer module. So, even though a dedup-compress instance 116 may have similarity groups 0-249, that dedup-compress instance 116 may still separate segments by their similarity group ID as they are sent to the packer module 120.

### C.3 Example Packer Module

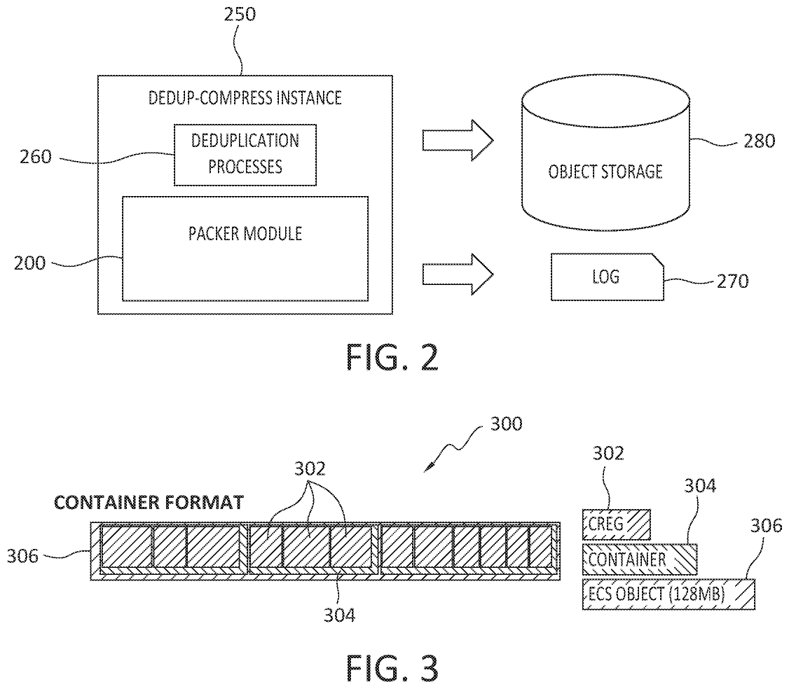

With continued attention to FIG. 1, and directing attention now to FIG. 2, as well, an example high-level figure of a packer module within a dedup-compress instance 250 is disclosed. A packer module such as the packer module 200 may also be an element of a GC instance if the GC instance runs as a separate service from the deduplication service 260. In some embodiments, the packer module 200 may be implemented as a container, such as a Kubernetes container for example, but no particular form of a packer module is required.

For segments that are unique, that is, segments that are not duplicates of segments already stored, the unique segments may be compressed into compression regions of approximately 64 KB in size. Again, the property is maintained such that all of the segments in a compression region are from the same similarity group. Compression regions may then be logged to a durable log 270 that has the property that it has low latency writes. In some embodiments, the log 270 may comprise flash memory and may be able to respond to writes within a few milliseconds, which is significantly faster than writes to object storage 280 which can be 10 s of milliseconds or longer in the public cloud. Once the compression regions are logged, the corresponding dedup-compress instance may acknowledge the write back to the client, since the data has been persisted and will accessible from the log 270 even if there are system failures.

With continued reference to FIG. 2, the packer module 200 may receive compression regions and form the larger object structure, comprising one or more compression regions, that will be written to object storage 280, such as DellEMC ECS or a public cloud, for example. In performing these operations, there may be a number of requirements that may need to be supported.

For example, relatively high throughput deduplication may be needed. In particular, consecutively written segments should remain together in storage and be represented with a set of fingerprints that can be loaded with one storage I/O (Input/Output operation) to a cache for deduplication. An example loading size for a set of fingerprints is approximately 1000 fingerprints, plus or minus about 45% to about 55%, or about 50% in some embodiments, but the loading size could be larger, or smaller, depending on the embodiment.

Another requirement may be that high random read performance may be needed. When clients perform a small read, such as about 8 KB, it may be desirable for the system to respond relatively quickly. Thus, it may be desirable to avoid performing a large read to the underlying storage to provide a small amount of data needed by a client. On the other hand, larger compression regions may tend to achieve more space savings since there is a greater chance for redundancy within the compression region. Some particular embodiments may employ compression regions having a size of approximately 64 KB, which supports good performance for small reads while also achieving the benefits of compression. The compression region size used in any particular case may be tuned to strike an acceptable balance between size and attendant space savings, and read performance.

A final example of a requirement is that the underlying object storage 280 may be optimized to handle a relatively large object size. For example, the object storage 280 may be optimized for 128 MB objects, which may avoid overheads for smaller-sized writes that incur mirrored write penalties. Public cloud providers may require a size of 1 MB or larger, and future object storage systems are likely to require fairly large-sized writes for the best performance. Depending upon public cloud parameters, such as the erasure coding size for example, the object size may be tuned accordingly.

### C.4 Example Container Format

To support various requirements, including those addressed in the discussion of FIG. 2, some embodiments of the packer module may implement a data structure 300 as shown in FIG. 3. As shown, one or more compression regions (‘Creg’) 302 are included in a container 304, and one or more containers 304 may be included in an object 306, such as an ECS object for example. In more detail, in the example of FIG. 3, compression regions 302 of approximately 64 KB each are packed into a container 304 holding approximately 1000 segments, and containers 304 are packed into the larger object 306 that will be written to object storage. In some embodiments, a container may be about 4 MB in size. This approach may meet the first requirement of high throughput deduplication by maintaining the locality of the approximately 1000 segments written sequentially. The fingerprints for these segments in a container are referred to as a container metadata structure, which may be loaded to a cache and used for deduplication. While the fingerprints could be stored in the container itself, or the object, container fingerprints may be placed in a <key,value> store in a key value store 106 or 108 (see FIG. 1) that may be backed by flash memory for fast access.

Example embodiments may provide an option to adjust the container size dynamically within the object based on locality properties. Briefly, locality refers to relative extent to which compression regions in a container are created with data from the same file. Because compression regions may include only unique segments, a file that has been backed up many times may arrive at a point where there are an inadequate number of compression regions to fill the container, and compression regions from another file, possibly in the same similarity group, are used to finish filling the container. In this case, locality may be said to be poor since the compression regions in the container include data from multiple different files. In contrast, a newly created file may have a substantial number of unique segments and the compression regions created with those segments are adequate to fill the container. In this case, locality may be said to be high, since all the data in the compression regions of the container may have come from the same file.

When locality is high, it may be reasonable to increase the container 304 size so that more fingerprints are loaded at a time. When locality is poor, then it may be better to have a smaller container 304 size and corresponding number of fingerprints in container metadata structure in the key values store as this reduces the overhead of reading fingerprints to a cache that are unlikely to be used for deduplication. Locality may be measured on the write path by maintaining a file tag with the segments so that segments from the same file are grouped together. During GC, it is likely that locality will decrease as segments from different files may be written together.

For a random read, a fingerprint index (not shown) provides a mapping from a fingerprint to the segment location so the compression region for that segment can be read in a single disk I/O. The compression region may be read, decompressed, and the needed data bytes are returned to the client. A packer module, such as the packer module 200, may be configured to create an object of the appropriate size for the underlying object storage 280. Some object storage systems, such as the DellEMC ECS for example, may be configured to have the best performance for 128 MB objects. Smaller objects, or the end pieces of larger objects, are less efficiently written to hard drives because they are three way mirrored and later erasure encoded once 128 MB of data, possibly from multiple objects, has arrived. For a 128 MB write for example, the mirroring may be skipped, and the data is directly erasure encoded. Public cloud providers seem to currently support good performance for 1 MB or larger objects, but the optimal size may increase in the future and may be tuned for each object storage provider. By aligning the object size to the tracking size of the underlying storage, when an object is deleted, the underlying storage system can simply free that space and not need to perform its own complicated cleaning.

### C.5 Garbage Collection

As noted, example embodiments may establish and maintain the property that all of the segments in a compression region, container, and object come from the same similarity group. For the container, this means that all of the segment fingerprints in a container metadata structure are from the same similarity group and may be used for deduplicating segments in a L1 of the same similarity group. For the object, this property may support parallel and focused garbage collection. Particularly, the similarity groups to be cleaned may be distributed across instances of a garbage collection service. When processing an object, a single garbage collection instance has unique access to that object if all of the segments are from one similarity group. Also, a garbage collection instance can focus on tracking the liveness only of segments within a similarity group and clean the corresponding objects.

### D. Example Methods

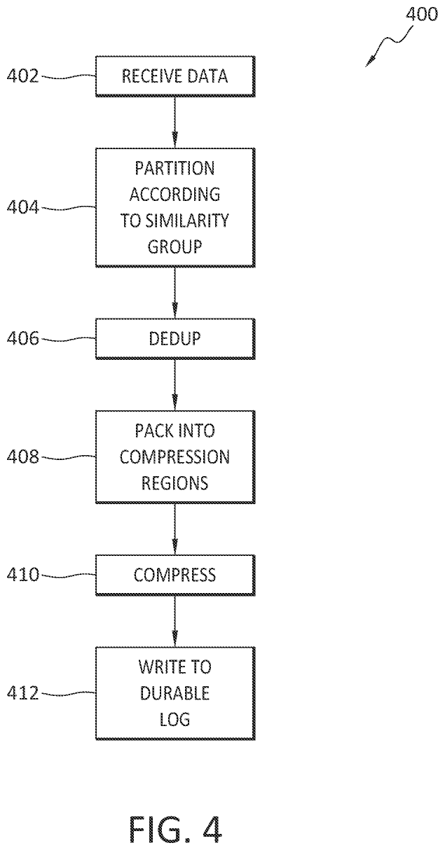

It is noted with respect to the example method of FIG. 4 that any of the disclosed processes, operations, methods, and/or any portion of any of these, may be performed in response to, as a result of, and/or, based upon, the performance of any preceding process(es), methods, and/or, operations. Correspondingly, performance of one or more processes, for example, may be a predicate or trigger to subsequent performance of one or more additional processes, operations, and/or methods. Thus, for example, the various processes that may make up a method may be linked together or otherwise associated with each other by way of relations such as the examples just noted. Finally, and while it is not required, the individual processes that make up the various example methods disclosed herein are, in some embodiments, performed in the specific sequence recited in those examples. In other embodiments, the individual processes that make up a disclosed method may be performed in a sequence other than the specific sequence recited.

Directing attention now to FIG. 4, details are provided concerning an example method 400 according to some embodiments of the invention. The method 400 may begin at 402 where data is received as a result of one or more client write processes. The incoming data may then be partitioned 404 according to similarity group.

The partitioned data may then be deduplicated 406, such as by a dedup-compress instance. In some embodiments, a respective dedup-compress instance may be assigned to a subset of similarity groups within a range of similarity groups. Thus, each dedup-compress instance may be responsible for performing deduplication and compression on data of the similarity groups to which that dedup-compress instance has been assigned.

After deduplication 406, the remaining unique segments may then be packed 408 into compression regions. The compression regions may then be compressed 410, such as by a dedup-compress instance. The compression regions may be combined together in a single container, and that container combined with other containers to create an object. The object may then be written 412 to a durable log. At some point after the object is written 412, the object may be moved to object storage.

### E. Further Example Embodiments

Following are some further example embodiments of the invention. These are presented only by way of example and are not intended to limit the scope of the invention in any way.

Embodiment 1. A method comprising the operations: receiving data; partitioning the data according to their respective similarity groups, and the similarity groups collectively define a range of similarity groups; deduplicating the data after the partitioning; packing unique data segments remaining after deduplicating into one or more compression regions; compressing the compression regions; and writing an object, that includes the compression regions, to a durable log.

Embodiment 2. The method as recited in embodiment 1, wherein the object includes one or more containers, and one of the containers includes the compression regions.

Embodiment 3. The method as recited in any of embodiments 1-2, wherein the operations further comprise combining the compression regions into a container, and combining the container with one or more additional containers to form the object.

Embodiment 4. The method as recited in any of embodiments 1-2, wherein a size of a container that is included in the object is adjusted based on a locality of data stored in the container.

Embodiment 5. The method as recited in any of embodiments 1-4, wherein a respective dedup-compress instance is assigned to each of the similarity groups in the range of similarity groups, and only the respective dedup-compress instance performs deduplication and compression for the similarity group to which that dedup-compress instance is assigned.

Embodiment 6. The method as recited in any of embodiments 1-5, wherein all data segments in the compression regions and the object come from the same similarity group.

Embodiment 7. The method as recited in any of embodiments 1-6, wherein the object is accessible at the log even in the event of a system failure.

Embodiment 8. The method as recited in any of embodiments 1-7, wherein the object is moved to object storage at some point after being written to the durable log, and the object storage has a higher latency for read and write operations than a latency of the durable log for read and write operations.

Embodiment 9. The method as recited in any of embodiments 1-8, wherein the packing is performed by a packer module that is an element of a dedup-compress instance that performs the deduplicating and the compressing.

Embodiment 10. The method as recited in any of embodiments 1-9, wherein the unique data segments in a compression region are consecutively written and are represented with a set of fingerprints that are loadable with one storage I/O to a cache prior to deduplication.

Embodiment 11. A method for performing any of the operations, methods, or processes, or any portion of any of these, disclosed herein.

Embodiment 12. A non-transitory storage medium having stored therein instructions that are executable by one or more hardware processors to perform operations comprising the operations of any one or more of embodiments 1-11.

### F. Example Computing Devices and Associated Media

The embodiments disclosed herein may include the use of a special purpose or general-purpose computer including various computer hardware or software modules, as discussed in greater detail below. A computer may include a processor and computer storage media carrying instructions that, when executed by the processor and/or caused to be executed by the processor, perform any one or more of the methods disclosed herein, or any part(s) of any method disclosed.

As indicated above, embodiments within the scope of the present invention also include computer storage media, which are physical media for carrying or having computer-executable instructions or data structures stored thereon. Such computer storage media may be any available physical media that may be accessed by a general purpose or special purpose computer.

By way of example, and not limitation, such computer storage media may comprise hardware storage such as solid state disk/device (SSD), RAM, ROM, EEPROM, CD-ROM, flash memory, phase-change memory (“PCM”), or other optical disk storage, magnetic disk storage or other magnetic storage devices, or any other hardware storage devices which may be used to store program code in the form of computer-executable instructions or data structures, which may be accessed and executed by a general-purpose or special-purpose computer system to implement the disclosed functionality of the invention. Combinations of the above should also be included within the scope of computer storage media. Such media are also examples of non-transitory storage media, and non-transitory storage media also embraces cloud-based storage systems and structures, although the scope of the invention is not limited to these examples of non-transitory storage media.

Computer-executable instructions comprise, for example, instructions and data which, when executed, cause a general purpose computer, special purpose computer, or special purpose processing device to perform a certain function or group of functions. As such, some embodiments of the invention may be downloadable to one or more systems or devices, for example, from a website, mesh topology, or other source. As well, the scope of the invention embraces any hardware system or device that comprises an instance of an application that comprises the disclosed executable instructions.

Although the subject matter has been described in language specific to structural features and/or methodological acts, it is to be understood that the subject matter defined in the appended claims is not necessarily limited to the specific features or acts described above. Rather, the specific features and acts disclosed herein are disclosed as example forms of implementing the claims.

As used herein, the term ‘module’ or ‘component’ may refer to software objects or routines that execute on the computing system. The different components, modules, engines, and services described herein may be implemented as objects or processes that execute on the computing system, for example, as separate threads. While the system and methods described herein may be implemented in software, implementations in hardware or a combination of software and hardware are also possible and contemplated. In the present disclosure, a ‘computing entity’ may be any computing system as previously defined herein, or any module or combination of modules running on a computing system.

In at least some instances, a hardware processor is provided that is operable to carry out executable instructions for performing a method or process, such as the methods and processes disclosed herein. The hardware processor may or may not comprise an element of other hardware, such as the computing devices and systems disclosed herein.

In terms of computing environments, embodiments of the invention may be performed in client-server environments, whether network or local environments, or in any other suitable environment. Suitable operating environments for at least some embodiments of the invention include cloud computing environments where one or more of a client, server, or other machine may reside and operate in a cloud environment.

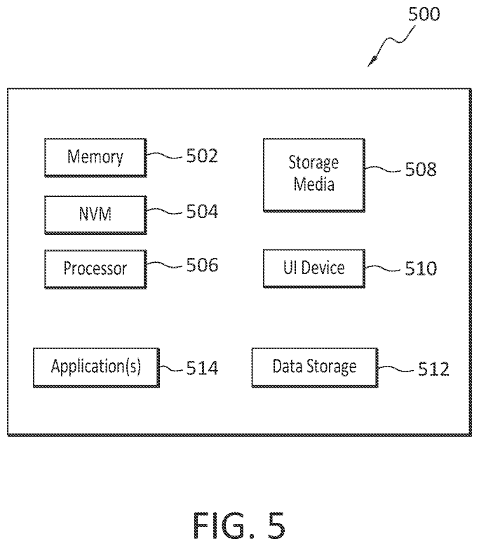

With reference briefly now to FIG. 5, any one or more of the entities disclosed, or implied, by FIGS. 1-4 and/or elsewhere herein, may take the form of, or include, or be implemented on, or hosted by, a physical computing device, one example of which is denoted at 500. As well, where any of the aforementioned elements comprise or consist of a virtual machine (VM), that VM may constitute a virtualization of any combination of the physical components disclosed in FIG. 5.

In the example of FIG. 5, the physical computing device 500 includes a memory 502 which may include one, some, or all, of random access memory (RAM), non-volatile memory (NVM) 504 such as NVRAM for example, read-only memory (ROM), and persistent memory, one or more hardware processors 506, non-transitory storage media 508, UI device 510, and data storage 512. One or more of the memory components 502 of the physical computing device 504 may take the form of solid state device (SSD) storage. As well, one or more applications 514 may be provided that comprise instructions executable by one or more hardware processors 506 to perform any of the operations, or portions thereof, disclosed herein.

Such executable instructions may take various forms including, for example, instructions executable to perform any method or portion thereof disclosed herein, and/or executable by/at any of a storage site, whether on-premises at an enterprise, or a cloud computing site, client, datacenter, data protection site including a cloud storage site, or backup server, to perform any of the functions disclosed herein. As well, such instructions may be executable to perform any of the other operations and methods, and any portions thereof, disclosed herein.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method, comprising the operations:
receiving data;
partitioning the data according to their respective similarity groups, and the similarity groups collectively define a range of similarity groups;
deduplicating the data after the partitioning;
packing unique data segments remaining after deduplicating into one or more compression regions;
compressing the compression regions; and
writing an object, that includes the compression regions, to a durable log.

2. The method as recited in claim 1, wherein the object includes one or more containers, and one of the containers includes the compression regions.

3. The method as recited in claim 1, wherein the operations further comprise combining the compression regions into a container, and combining the container with one or more additional containers to form the object.

4. The method as recited in claim 1, wherein a size of a container that is included in the object is adjusted based on a locality of data stored in the container.

5. The method as recited in claim 1, wherein a respective dedup-compress instance is assigned to each of the similarity groups in the range of similarity groups, and only the respective dedup-compress instance performs deduplication and compression for the similarity group to which that dedup-compress instance is assigned.

6. The method as recited in claim 1, wherein all data segments in the compression regions and the object come from the same similarity group.

7. The method as recited in claim 1, wherein the object is accessible at the log even in the event of a system failure.

8. The method as recited in claim 1, wherein the object is moved to object storage at some point after being written to the durable log, and the object storage has a higher latency for read and write operations than a latency of the durable log for read and write operations.

9. The method as recited in claim 1, wherein the packing is performed by a packer module that is an element of a dedup-compress instance that performs the deduplicating and the compressing.

10. The method as recited in claim 1, wherein the unique data segments in a compression region are consecutively written and are represented with a set of fingerprints that are loadable with one storage I/O to a cache prior to deduplication.

11. A non-transitory storage medium having stored therein instructions that are executable by one or more hardware processors to perform operations comprising:
receiving data;
partitioning the data according to their respective similarity groups, and the similarity groups collectively define a range of similarity groups;
deduplicating the data after the partitioning;
packing unique data segments remaining after deduplicating into one or more compression regions;
compressing the compression regions; and
writing an object, that includes the compression regions, to a durable log.

12. The non-transitory storage medium as recited in claim 11, wherein the object includes one or more containers, and one of the containers includes the compression regions.

13. The non-transitory storage medium as recited in claim 11, wherein the operations further comprise combining the compression regions into a container, and combining the container with one or more additional containers to form the object.

14. The non-transitory storage medium as recited in claim 11, wherein a size of a container that is included in the object is adjusted based on a locality of data stored in the container.

15. The non-transitory storage medium as recited in claim 11, wherein a respective dedup-compress instance is assigned to each of the similarity groups in the range of similarity groups, and only the respective dedup-compress instance performs deduplication and compression for the similarity group to which that dedup-compress instance is assigned.

16. The non-transitory storage medium as recited in claim 11, wherein all data segments in the compression regions and the object come from the same similarity group.

17. The non-transitory storage medium as recited in claim 11, wherein the object is accessible at the log even in the event of a system failure.

18. The non-transitory storage medium as recited in claim 11, wherein the object is moved to object storage at some point after being written to the durable log, and the object storage has a higher latency for read and write operations than a latency of the durable log for read and write operations.

19. The non-transitory storage medium as recited in claim 11, wherein the packing is performed by a packer module that is an element of a dedup-compress instance that performs the deduplicating and the compressing.

20. The non-transitory storage medium as recited in claim 11, wherein the unique data segments in a compression region are consecutively written and are represented with a set of fingerprints that are loadable with one storage I/O to a cache prior to deduplication.
